(19) United States
(12) Patent Application Publication
(10) Pub. No.: US 2021/0155836 A1
(43) Pub. Date: May 27, 2021

(54) MAGNETIZABLE ABRASIVE PARTICLE AND METHOD OF MAKING THE SAME

(71) Applicant: 3M INNOVATIVE PROPERTIES COMPANY, St Paul, MN (US)

(72) Inventors: Adam D. Miller, Vadnais Heights, MN (US); Kenton D. Budd, Woodbury, MN (US)

(21) Appl. No.: 17/047,037

(22) PCT Filed: Apr. 4, 2019
(86) PCT No.: PCT/IB2019/052765

§ 371 Date: Oct. 12, 2020

Related U.S. Application Data
(60) Provisional application No. 62/713,021, filed on Aug. 1, 2018.
(60) Provisional application No. 62/656,634, filed on Apr. 12, 2018.

(51) Int. Cl. C09K 3/14; C23C 16/06; C23C 16/442

(52) U.S. Cl. CPC C09K 3/1445; C23C 16/442; C23C 16/06

(57) ABSTRACT

A magnetizable abrasive particle. The magnetizable abrasive particle has a ceramic particle having an outer surface; and a continuous metal coating on the outer surface; wherein the core hardness of the ceramic particle is at least 15 GPa; wherein the continuous metal coating comprises iron, cobalt or an alloy of iron and cobalt; and wherein the thickness of the continuous metal coating is less than 1000 nm. A method of making the magnetizable abrasive particle is also disclosed.

### BACKGROUND

Various types of abrasive articles are known in the art. For example, coated abrasive articles generally have abrasive particles adhered to a backing by a resinous binder material. Examples include sandpaper and structured abrasives having precisely shaped abrasive composites adhered to a backing. The abrasive composites generally include abrasive particles and a resinous binder.

Bonded abrasive articles include abrasive particles retained in a binder matrix that can be resinous or vitreous. This mixture of binder and abrasive is typically shaped into blocks, sticks, or wheels. Examples include, grindstones, cutoff wheels, hones, and whetstones.

Precise placement and orientation of abrasive particles in abrasive articles such as, for example, coated abrasive articles and bonded abrasive articles has been a source of continuous interest for many years.

For example, coated abrasive articles have been made using techniques such as electrostatic coating of abrasive particles to align crushed abrasive particles with the longitudinal axes perpendicular to the backing. Likewise, shaped abrasive particles have been aligned by mechanical methods as disclosed in U. S. Pat. Appl. Publ. No. 2013/0344786 A1 (Keipert). Additionally, U.S. Pat. No. 1,930,788 (Buckner) describes the use of magnetic flux to orient abrasive grain having a thin coating of iron dust in bonded abrasive articles.

There is a continuing need for new materials and methods for bonding magnetic materials to abrasive particles.

### SUMMARY

Thus, in one aspect, the present disclosure provides a magnetizable abrasive particle, comprising: a ceramic particle having an outer surface; and a continuous metal coating on the outer surface; wherein the core hardness of the ceramic particle is at least 15 GPa; wherein the continuous metal coating comprises iron, cobalt or an alloy of iron and cobalt; and wherein the thickness of the continuous metal coating is less than 1000 nm.

In another aspect, the present disclosure provides a method of making magnetizable abrasive particles, comprising: providing ceramic particles, each ceramic particle having a respective outer surface; coating the outer surfaces of the ceramic particles with a continuous metal coating through chemical vapor deposition; wherein the continuous metal coating comprises iron, cobalt or alloy of iron and cobalt.

In another aspect, the present disclosure provides magnetizable abrasive particles prepared according to the method of the present application.

In another aspect, the present disclosure provides an abrasive article comprising a plurality of magnetizable abrasive particles of the present application.

In another aspect, the present disclosure provides a method for making an abrasive article comprising: providing magnetizable abrasive particles of the present application on a substrate having a major surface; and applying a magnetic field to the magnetizable abrasive particles such that a majority of the magnetizable abrasive particles are oriented substantially perpendicular to the major surface.

Various aspects and advantages of exemplary embodiments of the present disclosure have been summarized. The above Summary is not intended to describe each illustrated embodiment or every implementation of the present disclosure. Further features and advantages are disclosed in the embodiments that follow. The Drawings and the Detailed Description that follow more particularly exemplify certain embodiments using the principles disclosed herein.

### Definitions

For the following defined terms, these definitions shall be applied for the entire Specification, including the claims, unless a different definition is provided in the claims or elsewhere in the Specification based upon a specific reference to a modification of a term used in the following definitions:

The terms “about” or “approximately” with reference to a numerical value or a shape means+/−five percent of the numerical value or property or characteristic, but also expressly includes any narrow range within the +/−five percent of the numerical value or property or characteristic as well as the exact numerical value. For example, a temperature of “about” 100° C. refers to a temperature from 95° C. to 105° C., but also expressly includes any narrower range of temperature or even a single temperature within that range, including, for example, a temperature of exactly 100° C. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

The term “ceramic” refers to any of various hard, brittle, heat- and corrosion-resistant materials made of at least one metallic element (which may include silicon) combined with oxygen, carbon, nitrogen, or sulfur. Ceramics may be crystalline or polycrystalline, for example.

The term “ferrimagnetic” refers to materials that exhibit ferrimagnetism. Ferrimagnetism is a type of permanent magnetism that occurs in solids in which the magnetic fields associated with individual atoms spontaneously align themselves, some parallel, or in the same direction (as in ferromagnetism), and others generally antiparallel, or paired off in opposite directions (as in antiferromagnetism). The magnetic behavior of single crystals of ferrimagnetic materials may be attributed to the parallel alignment; the diluting effect of those atoms in the antiparallel arrangement keeps the magnetic strength of these materials generally less than that of purely ferromagnetic solids such as metallic iron. Ferrimagnetism occurs chiefly in magnetic oxides known as ferrites. The spontaneous alignment that produces ferrimagnetism is entirely disrupted above a temperature called the Curie point, characteristic of each ferrimagnetic material. When the temperature of the material is brought below the Curie point, ferrimagnetism revives.

The term “ferromagnetic” refers to materials that exhibit ferromagnetism. Ferromagnetism is a physical phenomenon in which certain electrically uncharged materials strongly attract others. In contrast to other substances, ferromagnetic materials are magnetized easily, and in strong magnetic fields the magnetization approaches a definite limit called saturation. When a field is applied and then removed, the magnetization does not return to its original value. This phenomenon is referred to as hysteresis. When heated to a certain temperature called the Curie point, which is generally different for each substance, ferromagnetic materials lose their characteristic properties and cease to be magnetic; however, they become ferromagnetic again on cooling.

The terms “magnetic” and “magnetized” mean being ferromagnetic or ferrimagnetic at 20° C. or capable of being made so, unless otherwise specified. Preferably, magnetizable layers according to the present disclosure either have, or can be made to have by exposure to an applied magnetic field.

The term “magnetic field” refers to magnetic fields that are not generated by any astronomical body or bodies (e.g., Earth or the sun). In general, magnetic fields used in practice of the present disclosure have a field strength in the region of the magnetizable abrasive particles being oriented of at least about 10 gauss (1 mT), preferably at least about 100 gauss (10 mT), and more preferably at least about 1000 gauss (0.1 T).

The term “magnetizable” means capable of being magnetized or already in a magnetized state.

The term “moist” means slightly wet; damp.

The term “shaped abrasive particle” refers to a ceramic abrasive particle that has been intentionally shaped (e.g., extruded, die cut, molded, screen-printed) at some point during its preparation such that the resulting ceramic body is non-randomly shaped. The term “shaped abrasive particle” as used herein excludes ceramic bodies obtained by a mechanical crushing or milling operation.

The term “platey crushed abrasive particle”, which refers to a crushed abrasive particle resembling a platelet and/or flake that is characterized by a thickness that is less than the width and length. For example, the thickness may be less than ½, ⅓, ¼, ⅕, ⅙, 1/7, ⅛, 1/9, or even less than 1/10 of the length and/or width. Likewise, the width may be less than ½, ⅓, ¼, ⅕, ⅙, 1/7, ⅛, 1/9, or even less than 1/10 of the length.

The term “essentially free of” means containing less than 5 percent by weight (e.g., less than 4, 3, 2, 1, 0.1, or even less than 0.01 percent by weight, or even completely free) of, based on the total weight of the object being referred to.

The terms “precisely-shaped abrasive particle” refers to an abrasive particle wherein at least a portion of the abrasive particle has a predetermined shape that is replicated from a mold cavity used to form a precursor precisely-shaped abrasive particle that is sintered to form the precisely-shaped abrasive particle. A precisely-shaped abrasive particle will generally have a predetermined geometric shape that substantially replicates the mold cavity that was used to form the abrasive particle.

The term “length” refers to the longest dimension of an object.

The term “width” refers to the longest dimension of an object that is perpendicular to its length.

The term “thickness” refers to the longest dimension of an object that is perpendicular to both of its length and width.

The term “aspect ratio” is defined as the ratio of the long axis of the particle through the center of mass of the particle to the short axis of the particle through the center of mass of the particle.

The suffix “(s)” indicates that the modified word can be singular or plural.

The term “magnetic saturation” is the maximum induced magnetic moment that can be obtained in a magnetic field.

The term “magnetic remanence” is the magnetization that persist within a material upon reducing an external magnetic field to zero.

The term “coercivity” is the external magnetic field strength in which the induced magnetization of a material is zero.

The term “monodisperse” describes a size distribution in which all the particles are approximately the same size.

The terms “a”, “an”, and “the” include plural referents unless the content clearly dictates otherwise. Thus, for example, reference to a material containing “a compound” includes a mixture of two or more compounds.

### BRIEF DESCRIPTION OF THE DRAWINGS

The disclosure may be more completely understood in consideration of the following detailed description of various embodiments of the disclosure in connection with the accompanying figures, in which:

FIG. 1 is a schematic perspective view of exemplary magnetizable abrasive particle (rod) 100 useful for making an abrasive article according to the present disclosure.

FIG. 1A is a schematic cross-sectional view of magnetizable abrasive rod 100 taken along line 1A-1A.

FIG. 2 is a schematic top view of an exemplary magnetizable shaped abrasive particle according to the present disclosure.

FIG. 2A is a schematic cross-sectional view of a magnetizable shaped abrasive particle taken along line 2A-2A.

FIG. 3 is a schematic perspective view depicting agglomerated magnetizable abrasive particles.

FIG. 4 is a schematic perspective view depicting unagglomerated magnetizable abrasive particles.

FIG. 5 is a cross-sectional view of a coated abrasive article according to the present disclosure.

FIG. 6 is a photograph of magnetizable abrasive particles prepared in Example 2.

FIG. 7 is a photograph of an abrasive article with magnetically oriented abrasive particles from Example 8.

FIG. 8 is a photograph of abrasive particles with non-oriented abrasive particles from Comparative Example 1.

While the above-identified drawings, which may not be drawn to scale, set forth various embodiments of the present disclosure, other embodiments are also contemplated, as noted in the Detailed Description. In all cases, this disclosure describes the presently disclosed invention by way of representation of exemplary embodiments and not by express limitations. It should be understood that numerous other modifications and embodiments can be devised by those skilled in the art, which fall within the scope and spirit of this disclosure.

### DETAILED DESCRIPTION

Before any embodiments of the present disclosure are explained in detail, it is understood that the invention is not limited in its application to the details of use, construction, and the arrangement of components set forth in the following description. The invention is capable of other embodiments and of being practiced or of being carried out in various ways that will become apparent to a person of ordinary skill in the art upon reading the present disclosure. Also, it is understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. It is understood that other embodiments may be utilized and structural or logical changes may be made without departing from the scope of the present disclosure.

As used in this Specification, the recitation of numerical ranges by endpoints includes all numbers subsumed within that range (e.g., 1 to 5 includes 1, 1.5, 2, 2.75, 3, 3.8, 4, and 5, and the like).

Unless otherwise indicated, all numbers expressing quantities or ingredients, measurement of properties and so forth used in the Specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Presently described are magnetizable abrasive particles, methods of making such particles, and abrasive articles comprising such magnetizable abrasive particles.

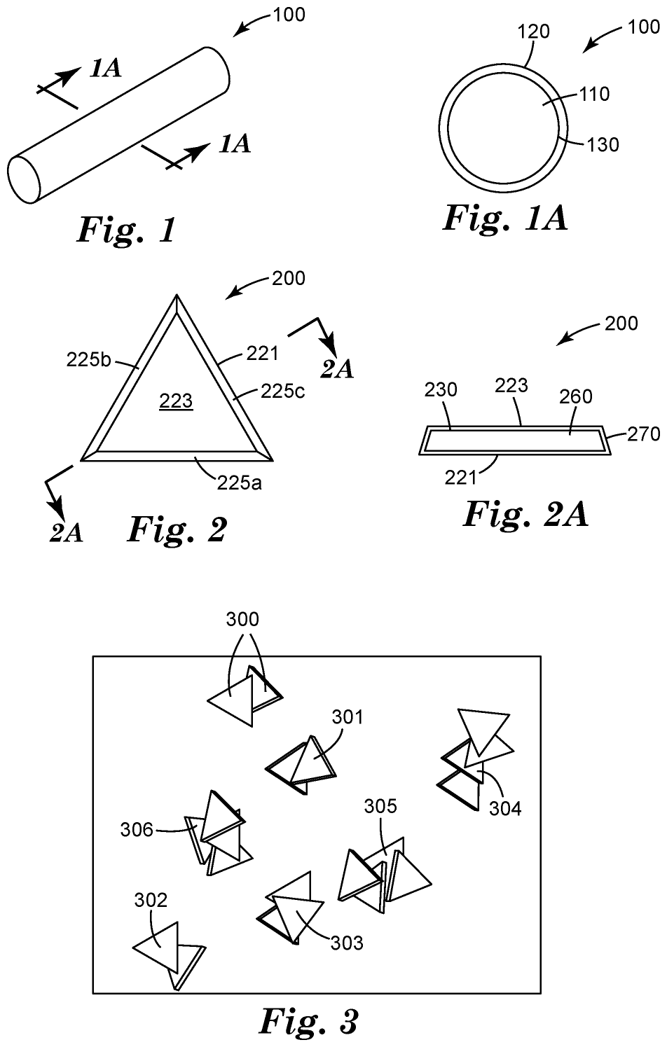

Referring to FIGS. 1 and 1A, exemplary magnetizable abrasive particle 100 that has a ceramic particle 110, having metal coating 120 disposed on its outer surface 130. In the embodiment of FIG. 1A, metal coating 120 is on the entire outer surface 130 of ceramic particle 110. Alternatively, metal coating 120 can be on a part of outer surface 130 of ceramic particle 110. In some embodiments, metal coating 120 can be a continuous metal coating. In the embodiment of FIGS. 1 and 1A, ceramic particle 110 is cylindrically-shaped. In other embodiments, for example, in FIGS. 2 and 2A, exemplary magnetizable abrasive particle 200 comprises truncated triangular ceramic particle 260 having metal coating 270 disposed on its outer surface 230. Metal coating 270 has opposed major surfaces 221, 223 connected to each other by sidewalls 225a, 225b, 225c.

The ceramic particles can be particles of any abrasive material. Useful ceramic materials include, for example, fused aluminum oxide, heat treated aluminum oxide, white fused aluminum oxide, ceramic aluminum oxide materials such as those commercially available as 3M CERAMIC ABRASIVE GRAIN from 3M Company of St. Paul, Minn., black silicon carbide, green silicon carbide, titanium diboride, boron carbide, tungsten carbide, titanium carbide, cubic boron nitride, garnet, fused alumina zirconia, sol-gel derived ceramics (e.g., alumina ceramics doped with chromia, ceria, zirconia, titania, silica, and/or tin oxide), silica (e.g., quartz, glass beads, glass bubbles and glass fibers), feldspar, or flint. Examples of sol-gel derived crushed ceramic particles can be found in U.S. Pat. No. 4,314,827 (Leitheiser et al.), U.S. Pat. No. 4,623,364 (Cottringer et al.); U.S. Pat. No. 4,744,802 (Schwabel), U.S. Pat. No. 4,770,671 (Monroe et al.); and U.S. Pat. No. 4,881,951 (Monroe et al.). Further details concerning methods of making sol-gel-derived abrasive particles can be found in, for example, U.S. Pat. No. 4,314,827 (Leitheiser), U.S. Pat. No. 5,152,917 (Pieper et al.), U.S. Pat. No. 5,213,591 (Celikkaya et al.), U.S. Pat. No. 5,435,816 (Spurgeon et al.), U.S. Pat. No. 5,672,097 (Hoopman et al.), U.S. Pat. No. 5,946,991 (Hoopman et al.), U.S. Pat. No. 5,975,987 (Hoopman et al.), and U.S. Pat. No. 6,129,540 (Hoopman et al.), and in U.S. Publ. Pat. Appln. Nos. 2009/0165394 A1 (Culler et al.) and 2009/0169816 A1 (Erickson et al.).

The ceramic particles may be shaped (e.g., precisely-shaped) or random (e.g., crushed and/or platey). Shaped ceramic particles and precisely-shaped ceramic particles may be prepared by a molding process using sol-gel technology as described, for example, in U.S. Pat. No. 5,201,916 (Berg), U.S. Pat. No. 5,366,523 (Rowenhorst (Re 35,570)), U.S. Pat. No. 5,984,988 (Berg), U.S. Pat. No. 8,142,531 (Adefris et al.), and U.S. Pat. No. 8,764,865 (Boden et al.).

U.S. Pat. No. 8,034,137 (Erickson et al.) describes ceramic alumina particles that have been formed in a specific shape, then crushed to form shards that retain a portion of their original shape features. In some embodiments, the ceramic particles are precisely-shaped (i.e., the ceramic particles have shapes that are at least partially determined by the shapes of cavities in a production tool used to make them).

Exemplary shapes of ceramic particles include crushed, pyramids (e.g., 3-, 4-, 5-, or 6-sided pyramids), truncated pyramids (e.g., 3-, 4-, 5-, or 6-sided truncated pyramids), cones, truncated cones, rods (e.g., cylindrical, vermiform), and prisms (e.g., 3-, 4-, 5-, or 6-sided prisms). In some embodiments (e.g., truncated pyramids and prisms), the ceramic particles respectively comprise platelets having two opposed major facets connected to each other by a plurality of side facets.

In some embodiments, the ceramic particles preferably comprise crushed abrasive particles having an aspect ratio of at least 1.73, at least 2, at least 3, at least 5, or even at least 10.

Preferably, ceramic particles used in practice of the present disclosure have a core hardness of at least 6, at least 7, at least 8, or at least 15 GPa.

Further details concerning ceramic particles suitable for use as abrasive particles and methods for their preparation can be found, for example, in U.S. Pat. No. 8,142,531 (Adefris et al.), U.S. Pat. No. 8,142,891 (Culler et al.), and U.S. Pat. No. 8,142,532 (Erickson et al.), and in U.S. Pat. Appl. Publ. Nos. 2012/0227333 (Adefris et al.), 2013/0040537 (Schwabel et al.), and 2013/0125477 (Adefris).

In some embodiments, the metal coating covers the ceramic particle thereby enclosing it. The metal coating may be a unitary magnetizable material (e.g., vapor-coated magnetizable metal). Exemplary useful magnetizable materials for use in the metal coating may comprise: iron; cobalt; or an alloy of iron and cobalt. In some embodiments, the metal coating consists essentially of iron, cobalt or alloy of iron and cobalt, for example, more than 95% metal coating comprises iron, cobalt or alloy of iron and cobalt. In some embodiments, the metal coating may be deposited using a vapor deposition technique such as, for example, chemical vapor deposition (CVD). Metal coating can typically be prepared in this general manner.

The thickness of the metal coating is less than 1000 nm, less than 500 nm, less than 300 nm, less than 200 nm, less than 100 nm, or less than 50 nm. The magnetic saturation of the magnetic metal coating is preferably at least 1, 2, 3, 4, 5, 6, 7, 8, or 10 emu/g with a field strength of 18 kOe. In some embodiments, the magnetic saturation of the metal coating is greater than 10 with a field strength of 18 kOe such as at least 15, 20, 25, 30, 35, 40, 45, 50, 55, or 60 emu/g. In some embodiments, the magnetic saturation of the metal coating is at least 65 or 70 emu/g with a field strength of 18 kOe. In some embodiments, the magnetic saturation of the metal coating is at least 75, 80, 85, 90 or 95 emu/g with a field strength of 18 kOe. In some embodiments, the magnetic saturation of the metal coating is at least 100, 115, 120, 125, 130, or 135 emu/g with a field strength of 18 kOe. The magnetic saturation of the metal coating is typically no greater than 250 emu/gram. Higher magnetic saturation can be amenable to providing magnetizable ceramic particles with less metal coating per mass of ceramic particles. In some embodiments, the coercivity of the metal coating is less than 500 Oe (oersteds). In some embodiments, the coercivity is less than 350, 300, 250, 200, 150, or 100 Oe. The coercivity is typically at least 1 Oe and in some embodiments at least 5, 10, 15, 20, 25, 30, 35, 40, 45, or 50 Oe. In some embodiments, a ratio of magnetic remanence (M_{R}) to magnetic saturation (M_{S}) of is less than 65%.

Methods of making magnetizable abrasive particles according to the present disclosure include a series of sequential steps, which may be consecutive or not.

In a first step, ceramic particles are provided, each ceramic particle having a respective outer surface. In a subsequent step, the method comprises coating the outer surfaces of ceramic particles with a continuous metal coating through chemical vapor deposition. The metal coating may comprise: iron; cobalt; or an alloy of iron and cobalt. In some embodiments, the ceramic particles comprise aluminum oxide, or in other words alumina. For example, in some embodiments, the ceramic particles comprise at least 50, 60, 70, 80, 90, 95, or even 100% alumina. When the ceramic particles comprise less than 100 wt.-% alumina, the remainder of the ceramic particles is typically a metal oxide. The chemical vapor deposition is typically carried out at essentially atmospheric pressure. The chemical vapor deposition is often carried out in a fluidized bed. In some embodiments, the chemical vapor deposition is carried out in a rotary kiln. In some embodiments, the chemical vapor deposition comprises thermal decomposition of iron pentacarbonyl.

Magnetizable abrasive particles and/or ceramic particles used in their manufacture according to the present disclosure may be independently sized according to an abrasives industry recognized specified nominal grade. Exemplary abrasive industry recognized grading standards include those promulgated by ANSI (American National Standards Institute), FEPA (Federation of European Producers of Abrasives), and JIS (Japanese Industrial Standard). ANSI grade designations (i.e., specified nominal grades) include, for example: ANSI 4, ANSI 6, ANSI 8, ANSI 16, ANSI 24, ANSI 36, ANSI 46, ANSI 54, ANSI 60, ANSI 70, ANSI 80, ANSI 90, ANSI 100, ANSI 120, ANSI 150, ANSI 180, ANSI 220, ANSI 240, ANSI 280, ANSI 320, ANSI 360, ANSI 400, and ANSI 600. FEPA grade designations include F4, F5, F6, F7, F8, F10, F12, F14, F16, F16, F20, F22, F24, F30, F36, F40, F46, F54, F60, F70, F80, F90, F100, F120, F150, F180, F220, F230, F240, F280, F320, F360, F400, F500, F600, F800, F1000, F1200, F1500, and F2000. JIS grade designations include JIS8, JIS12, JIS16, JIS24, JIS36, JIS46, JIS54, JIS60, JIS80, JIS100, JIS150, JIS180, JIS220, JIS240, JIS280, JIS320, JIS360, JIS400, JIS600, JIS800, JIS1000, JIS1500, JIS2500, JIS4000, JIS6000, JIS8000, and JIS10,000.

Alternatively, magnetizable abrasive particles and/or ceramic particles used in their manufacture according to the present disclosure can be graded to a nominal screened grade using U.S. A. Standard Test Sieves conforming to ASTM E-11 “Standard Specification for Wire Cloth and Sieves for Testing Purposes”. ASTM E-11 prescribes the requirements for the design and construction of testing sieves using a medium of woven wire cloth mounted in a frame for the classification of materials according to a designated particle size. A typical designation may be represented as −18+20 meaning that the ceramic particles pass through a test sieve meeting ASTM E-11 specifications for the number 18 sieve and are retained on a test sieve meeting ASTM E-11 specifications for the number 20 sieve. In one embodiment, the ceramic particles have a particle size such that most of the particles pass through an 18 mesh test sieve and can be retained on a 20, 25, 30, 35, 40, 45, or 50 mesh test sieve. In various embodiments, the ceramic particles can have a nominal screened grade of: −18+20, −20+25, −25+30, −30+35, −35+40, −40+45, −45+50, −50+60, −60+70, −70+80, −80+100, −100+120, −120+140, −140+170, −170+200, −200+230, −230+270, −270+325, −325+400, −400+450, −450+500, or −500+635. Alternatively, a custom mesh size can be used such as −90+100.

In other embodiments, it has been found that the method of coating ceramic particles with continuous metal coating through chemical vapor deposition can reduce the agglomeration of the magnetizable abrasive particles thus formed.

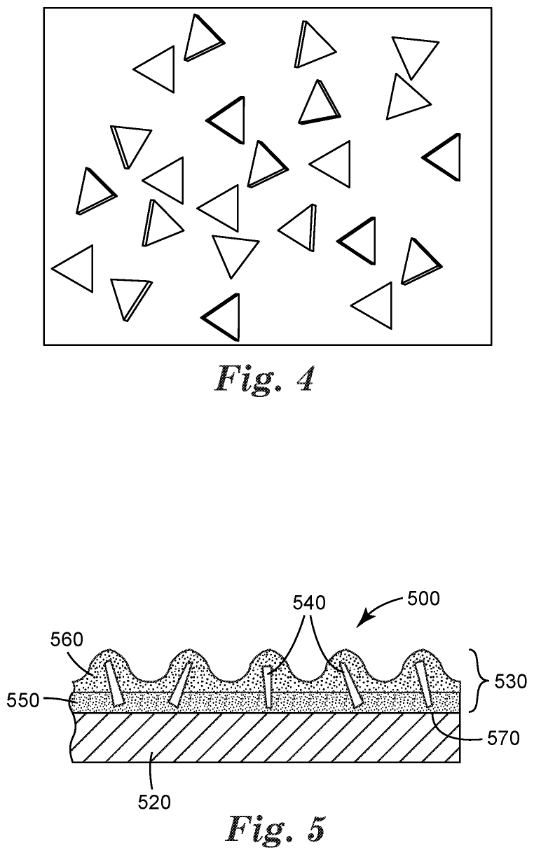

An “agglomerate” refers to a weak association between primary particles which may be held together by charge or polarity and can be broken down into smaller entities. FIG. 3 depicts some examples of magnetizable abrasive particles in the form of agglomerates. The agglomerate comprises at least two magnetizable abrasive particles agglomerated to each other such as in the case of agglomerates 300, 301, and 302. In other embodiments, the agglomerates comprise three magnetizable abrasive particles agglomerated to each other such as in the case of agglomerates 303. In yet other embodiments, the agglomerate comprises four magnetizable abrasive particles agglomerated to each other such as in the case of agglomerates 304, 305, or 306. In yet other embodiments (not shown) the agglomerate can comprise more than four magnetizable abrasive particles agglomerated to each other. Agglomerated magnetizable abrasive particles cannot be oriented in the same manner as single, discreet, unagglomerated magnetizable abrasive particles. In some embodiments, a majority of the magnetizable abrasive particles (i.e., at least 50%) are present as discrete unagglomerated particles, such as depicted in FIG. 4. For example, at least 60%, 65%, 70%, 75%, 80%, 85%, 90%, 95%, or 99%, or greater of the magnetizable abrasive particles are present as discrete unagglomerated particles. In some embodiments, magnetizable abrasive particles are essentially free of agglomerated magnetizable abrasive particles.

Magnetizable abrasive particles prepared according to the present disclosure can be used in loose form (e.g., free-flowing or in a slurry) or they may be incorporated into various abrasive articles (e.g., coated abrasive articles, bonded abrasive articles, nonwoven abrasive articles, and/or abrasive brushes). Due to their anisotropic magnetic properties, the magnetizable abrasive particles can be oriented and manipulated using a magnetic field to provide the above various abrasive articles with controlled abrasive particle orientation and position.

In one embodiment, the method of making an abrasive article comprises:

a) providing the magnetizable abrasive particles described herein on a substrate having a major surface; and

b) applying a magnetic field to the magnetizable abrasive particles such that a majority of the magnetizable abrasive particles are oriented substantially perpendicular to the major surface.

If no magnetic field is applied in step b), then the resultant magnetizable abrasive particles may not have a magnetic moment, and the constituent abrasive particles, or magnetizable abrasive particles may be randomly oriented. However, when a sufficient magnetic field is applied the magnetizable abrasive particles will tend to align with the magnetic field. In favored embodiments, the ceramic particles have a major axis (e.g. aspect ratio of 2) and the major axis aligns parallel to the magnetic field. Preferably, a majority or even all of the magnetizable abrasive particles will have magnetic moments that are aligned substantially parallel to one another.

The magnetic field can be supplied by any external magnet (e.g., a permanent magnet or an electromagnet). In some embodiments, the magnetic field typically ranges from 0.5 to 1.5 kOe. Preferably, the magnetic field is substantially uniform on the scale of individual magnetizable abrasive particles.

For production of abrasive articles, a magnetic field can optionally be used to place and/or orient the magnetizable abrasive particles prior to curing the binder (e.g., vitreous or organic) precursor to produce the abrasive article. The magnetic field may be substantially uniform over the magnetizable abrasive particles before they are fixed in position in the binder or continuous over the entire, or it may be uneven, or even effectively separated into discrete sections. Typically, the orientation of the magnetic field is configured to achieve alignment of the magnetizable abrasive particles according to a predetermined orientation.

Examples of magnetic field configurations and apparatuses for generating them are described in U.S. Pat. No. 8,262,758 (Gao) and U.S. Pat. No. 2,370,636 (Carlton), U.S. Pat. No. 2,857,879 (Johnson), U.S. Pat. No. 3,625,666 (James), U.S. Pat. No. 4,008,055 (Phaal), U.S. Pat. No. 5,181,939 (Neff), and British (G. B.) Pat. No. 1 477 767 (Edenville Engineering Works Limited).

In some embodiments, a magnetic field may be used to deposit the magnetizable abrasive particles onto the binder precursor of a coated abrasive article while maintaining a vertical or inclined orientation relative to a horizontal backing. After drying and/or at least partially curing the binder precursor, the magnetizable abrasive particles are fixed in their placement and orientation. Alternatively or in addition, the presence or absence of strong magnetic field can be used to selectively place the magnetizable abrasive particles onto the binder precursor. An analogous process may be used for manufacture of slurry coated abrasive articles, except that the magnetic field acts on the magnetizable particles within the slurry. The above processes may also be carried out on nonwoven backings to make nonwoven abrasive articles.

Likewise, in the case of bonded abrasive article, the magnetizable abrasive particles can be positioned and/or orientated within the corresponding binder precursor, which is then pressed and cured.

Referring to FIG. 5, an illustrative coated abrasive article 500 has backing 520 and abrasive layer 530. Abrasive layer 530, includes magnetizable abrasive particles 540 according to the present disclosure secured to surface 570 of backing 520 by binder layer 550. The coated abrasive article 500 may further comprise an optional size layer 560 that may comprise the same or different binder than binder layer 550. Various binder layers for abrasive articles are known including, for example, epoxy resin, urethane resin, phenolic resin, aminoplast resin, or acrylic resin.

Further details concerning the manufacture of coated abrasive articles according to the present disclosure can be found in, for example, U.S. Pat. No. 4,314,827 (Leitheiser et al.), U.S. Pat. No. 4,652,275 (Bloecher et al.), U.S. Pat. No. 4,734,104 (Broberg), U.S. Pat. No. 4,751,137 (Tumey et al.), U.S. Pat. No. 5,137,542 (Buchanan et al.), U.S. Pat. No. 5,152,917 (Pieper et al.), U.S. Pat. No. 5,417,726 (Stout et al.), U.S. Pat. No. 5,573,619 (Benedict et al.), U.S. Pat. No. 5,942,015 (Culler et al.), and U.S. Pat. No. 6,261,682 (Law).

Nonwoven abrasive articles typically include a porous (e.g., a lofty open porous) polymer filament structure having magnetizable abrasive particles bonded thereto by a binder. Further details concerning the manufacture of nonwoven abrasive articles according to the present disclosure can be found in, for example, U.S. Pat. No. 2,958,593 (Hoover et al.), U.S. Pat. No. 4,018,575 (Davis et al.), U.S. Pat. No. 4,227,350 (Fitzer), U.S. Pat. No. 4,331,453 (Dau et al.), U.S. Pat. No. 4,609,380 (Barnett et al.), U.S. Pat. No. 4,991,362 (Heyer et al.), U.S. Pat. No. 5,554,068 (Carr et al.), U.S. Pat. No. 5,712,210 (Windisch et al.), U.S. Pat. No. 5,591,239 (Edblom et al.), U.S. Pat. No. 5,681,361 (Sanders), U.S. Pat. No. 5,858,140 (Berger et al.), U.S. Pat. No. 5,928,070 (Lux), U.S. Pat. No. 6,017,831 (Beardsley et al.), U.S. Pat. No. 6,207,246 (Moren et al.), and U.S. Pat. No. 6,302,930 (Lux).

Abrasive articles according to the present disclosure are useful for abrading a workpiece. Methods of abrading range from snagging (i.e., high pressure high stock removal) to polishing (e.g., polishing medical implants with coated abrasive belts), wherein the latter is typically done with finer grades of abrasive particles. One such method includes the step of frictionally contacting an abrasive article (e.g., a coated abrasive article, a nonwoven abrasive article, or a bonded abrasive article) with a surface of the workpiece, and moving at least one of the abrasive article or the workpiece relative to the other to abrade at least a portion of the surface.

Examples of workpiece materials include metal, metal alloys, exotic metal alloys, ceramics, glass, wood, wood-like materials, composites, painted surfaces, plastics, reinforced plastics, stone, and/or combinations thereof. The workpiece may be flat or have a shape or contour associated with it. Exemplary workpieces include metal components, plastic components, particleboard, camshafts, crankshafts, furniture, and turbine blades.

Abrasive articles according to the present disclosure may be used by hand and/or used in combination with a machine. At least one of the abrasive article and the workpiece is moved relative to the other when abrading. Abrading may be conducted under wet or dry conditions. Exemplary liquids for wet abrading include water, water containing conventional rust inhibiting compounds, lubricant, oil, soap, and cutting fluid. The liquid may also contain defoamers, degreasers, for example.

The following embodiments are intended to be illustrative of the present disclosure and not limiting.

### Embodiments

Embodiment 1 is a magnetizable abrasive particle, comprising: a ceramic particle having an outer surface; and a continuous metal coating on the outer surface; wherein the core hardness of the ceramic particle is at least 15 GPa; wherein the continuous metal coating comprises iron, cobalt or an alloy of iron and cobalt; and wherein the thickness of the continuous metal coating is less than 1000 nm.

Embodiment 2 is the magnetizable abrasive particle of embodiment 1, wherein the continuous metal coating consists essentially of iron, cobalt or alloy of iron and cobalt.

Embodiment 3 is the magnetizable abrasive particle of embodiments 1-2, wherein an aspect ratio of the ceramic particle is more than 1.73.

Embodiment 4 is the magnetizable abrasive particle of embodiments 1-3, wherein the metal coating of the abrasive particle has a coercivity (H_{C}) of less than 200 Oe.

Embodiment 5 is the magnetizable abrasive particle of embodiments 1-4, wherein the metal coating on the abrasive particle has a ratio of magnetic remanence (M_{R}) to magnetic saturation (M_{S}) of less than 65%.

Embodiment 6 is the magnetizable abrasive particle of embodiments 1-5, wherein the ceramic particle comprises alpha alumina.

Embodiment 7 is the magnetizable abrasive particle of embodiments 1-6, wherein the ceramic particle comprises a spheroid particle.

Embodiment 8 is the magnetizable abrasive particle of embodiments 1-6, wherein the ceramic particle comprises ceramic rods.

Embodiment 9 is the magnetizable abrasive particle of embodiments 1-6, wherein the ceramic particle comprises ceramic platelets.

Embodiment 10 is the magnetizable abrasive particle embodiment 9, wherein the ceramic platelets comprise ceramic truncated triangular pyramids.

Embodiment 11 is a method of making magnetizable abrasive particles, comprising: providing ceramic particles, each ceramic particle having a respective outer surface; coating the outer surfaces of ceramic particles with a continuous metal coating through chemical vapor deposition; wherein the continuous metal coating comprises iron, cobalt or alloy of iron and cobalt.

Embodiment 12 is the method of embodiment 11, wherein said chemical vapor deposition is carried out at essentially atmospheric pressure.

Embodiment 13 is the method of embodiments 11-12, wherein said chemical vapor deposition is carried out in a fluidized bed.

Embodiment 14 is the method of embodiments 11-12, wherein said chemical vapor deposition is carried out in a rotary kiln.

Embodiment 15 is the method of embodiments 11-14, wherein the magnetizable abrasive particles have less than 25% agglomerated magnetizable abrasive particles.

Embodiment 16 is the method of embodiments 11-15, wherein the magnetizable abrasive particles are essentially free of agglomerated magnetizable abrasive particles.

Embodiment 17 is magnetizable abrasive particles prepared according to any one of embodiments 11-16.

Embodiment 18 is an abrasive article comprising a plurality of magnetizable abrasive particles of embodiments 1-10.

Embodiment 19 is a method for making an abrasive article comprising: providing magnetizable abrasive particles of embodiments 1-10 on a substrate having a major surface; and applying a magnetic field to the magnetizable abrasive particles such that a majority of the magnetizable abrasive particles are oriented substantially perpendicular to the major surface.

The following working examples are intended to be illustrative of the present disclosure and not limiting.

### EXAMPLES

Materials

The materials with their sources were as listed in Table 1. Unless stated otherwise, all other reagents were obtained, or are available from fine chemical vendors such as Sigma-Aldrich Company, St. Louis, Mo., or may be synthesized by known methods.

TABLE 1
Materials List

| Designation | Description | Source |
|---|---|---|
| Iron | Pentacarbonyliron, 99.5% | Alfa Aesar, |
| pentacarbonyl | | Haverhill, MA, |
| | | USA |
| SAP1 | Shaped abrasive particles were prepared according to the | 3M Company, |
| | disclosure of U.S. Pat. No. 8,142,531 (Adefris et al). The | Maplewood, |
| | shaped abrasive particles were prepared by molding alumina | MN, USA |
| | sol gel in equilateral triangle-shaped polypropylene mold | |
| | cavities. After drying and firing, the resulting shaped | |
| | abrasive particles, which were shaped as truncated triangular | |
| | pyramids, were about 100 μm (side length) × 25 μm | |
| | (thickness), with a draft angle approximately 98 degrees | |
| SAP2 | Shaped abrasive particles were prepared according to the | 3M Company |
| | disclosure of U.S. Pat. No. 8,142,531 (Adefris et al). The | |
| | shaped abrasive particles were prepared by molding alumina | |
| | sol gel in equilateral triangle-shaped polypropylene mold | |
| | cavities. After drying and firing, the resulting shaped | |
| | abrasive particles were about 330 μm (side length) × 100 μm | |
| | (thickness), with a draft angle approximately 98 degrees. The | |
| | shaped abrasive particles were then coated with inorganic | |
| | material according to the method described in U.S. Pat. No. | |
| | 5,213,591 (Celikkaya et al). | |
| SAP3 | Shaped abrasive particles were prepared according to the | 3M Company |
| | disclosure of U.S. Pat. No. 8,142,531 (Adefris et al). The | |
| | shaped abrasive particles were prepared by molding alumina | |
| | sol gel in equilateral triangle-shaped polypropylene mold | |
| | cavities. After drying and firing, the resulting shaped | |
| | abrasive particles were about 520 μm (side length) × 150 μm | |
| | (thickness), with a draft angle approximately 98 degrees. | |
| SAP4 | Shaped abrasive particles were prepared according to the | 3M Company |
| | disclosure of U.S. Pat. No. 8,142,531 (Adefris et al). The | |
| | shaped abrasive particles were prepared by molding alumina | |
| | sol gel in equilateral triangle-shaped polypropylene mold | |
| | cavities. After drying and firing, the resulting shaped | |
| | abrasive particles were about 170 μm (side length) × 40 μm | |
| | (thickness), with a draft angle approximately 98 degrees. The | |
| | shaped abrasive particles were then coated with inorganic | |
| | material according to the method described in U.S. Pat. No. | |
| | 5,213,591 (Celikkaya et al). | |
| SAP5 | Alumina chopped fiber obtained under the trade designation | 3M Company |
| | 3M NEXTEL CHOPPED FIBER 720; 32 micrometers (μm) | |
| | diameter, about 200 μm length | |
| SAP6 | Shaped abrasive particles were prepared according to the | 3M Company |
| | disclosure of U.S. Pat. No. 8,142,531 (Adefris et al). The | |
| | shaped abrasive particles were prepared by molding alumina | |
| | sol gel in equilateral triangle-shaped polypropylene mold | |
| | cavities. After drying and firing, the resulting shaped | |
| | abrasive particles were about 1.4 mm (side length) × 0.35 mm | |
| | (thickness), with a draft angle approximately 98 degrees. The | |
| | shaped abrasive particles were then coated with inorganic | |
| | material according to the method described in U.S. Pat. No. | |
| | 5,213,591 (Celikkaya et al). | |
| SiC | Silicon carbide grade P150 sold under the trade name | Washington |
| | CARBOREX | Mills, Niagara |
| | | Falls, NY, |
| | | USA |
| Nitrogen | Inert gas, N₂ | Praxair, |
| | | Danbury, CT, |
| | | USA |
| Forming gas | 5% hydrogen balance nitrogen | Oxygen |
| | | Services |
| | | Company, St. |
| | | Paul, MN, |
| | | USA |
| 110 gsm paper | Obtained under the trade designation ARJOWET | Munksjo Paper |
| backing | | Inc, Bethune, |
| | | SC, USA |
| phenolic resin | Obtained as GP 8339 R-23155B | Georgia Pacific |
| | | Chemicals, |
| | | Atlanta, |
| | | GA, |
| | | USA |

### Test Methods

### Magnetic Properties Test Method

The magnetic properties of the magnetic particles (powders) were tested at room temperature with a Lake Shore 7400 Series vibrating sample magnetometer (VSM) (Lake Shore Cryotronics, Inc., Westerville, Ohio, USA). The mass of the magnetic particles was measured (balance model MS105DU, Mettler Toledo, Switzerland) prior to the magnetic measurements. The mass of the empty VSM sample holder, similar to a Lake Shore Model 730935 (P/N 651-454), was used to zero the balance. For each sample, a new VSM holder was used. After the magnetic particles were loaded into the VSM sample holder (into the approximately 15 millimeter (mm) tap of the holder), the mass of powder was measured. To secure the powder in the tap of the holder, adhesive (3M SCOTCH-WELD Instant Adhesive ID No. 62-3801-0330-9, 3M Company, Maplewood, Minn., USA) was applied. The adhesive dried for at least 4 hours prior to the measurement. The magnetic moment (emu) of the magnetic particles was measured at magnetic field H=18 kilooersted (kOe). The saturation magnetization M_{S} per mass of the abrasive particles (emu/g) was calculated by dividing measured magnetic moment at 18 kOe to the mass of the magnetic particles. For magnetic powders the measured coercive force H_{c} (Oe) and remnant magnetization Mᵣ/M_{S} was also recorded. These values were taken from the magnetization loops recorded by sweeping magnetic field H from +20 to −20 kOe. The sweeping speed of the magnetic field H for each measurement was 26.7 Oe/s.

### Elemental Analysis Test Method

The relative amount of iron to aluminum (or silicon) was measured with an Olympus Delta Professional handheld XRF analyzer from Olympus Corp., Japan. The samples were loaded into a 3 centimeter (cm) diameter sample cup with a 0.12 mil (0.003 mm) Mylar sample window such that the entire bottom of the sample window was covered with powder (about 5 mm deep). The weight percentage of the detected elements was determined from the “GeoChem” calibration of the instrument and the weight ratio of the elements of interest are presented in Table 3.

### Coating Thickness Measurement Test Method

The coating thickness was calculated based on the geometry of the particle and the amount of iron on the particle. The weight percentage of iron was calculated from the change in density after coating measured using helium pycnometry (Accu Pyc II TEC, Micromeritics Instrument Corp., Norcross, Ga., USA) assuming the coating was pure iron. The thicknesses are presented in Table 3.

### EXAMPLES

### Example 1 (EX-1)

Alumina in the shape of truncated equilateral triangular pyramids, SAP1, (100 grams (g)) were charged into a glass frit funnel-type fluidized bed chemical vapor deposition (CVD) reactor with 45 millimeters (mm) inner diameter reactor (as described, for example, in Example 1 of U.S. Pat. No. 5,673,148 (Morris et al)). The reactor was wrapped with electric heating tape and heated to 250° C. The temperature was monitored using a thermocouple in the fluidized bed. The bed of alumina particles was fluidized with a stream of 3.6 liter/minute (L/min) nitrogen gas introduced into the reactor through the glass frit (i.e., from the bottom of the bed of alumina particles). Iron pentacarbonyl vapor was simultaneously introduced into the reactor, above the glass frit, in a stream of 300 cubic centimeters per minute (cc/min) nitrogen carrier gas by bubbling the carrier gas through iron pentacarbonyl in a chamber separate from the reactor. After 80 minutes of total reaction time, the power to the electric heating tape and the nitrogen flow through the iron pentacarbonyl were turned off. The alumina particles were cooled under a flow of nitrogen through the glass fit to about 40° C. and were collected to give alumina particles with a shiny, metallic coating.

### Examples 2 to 5 (EX-2 to EX-5)

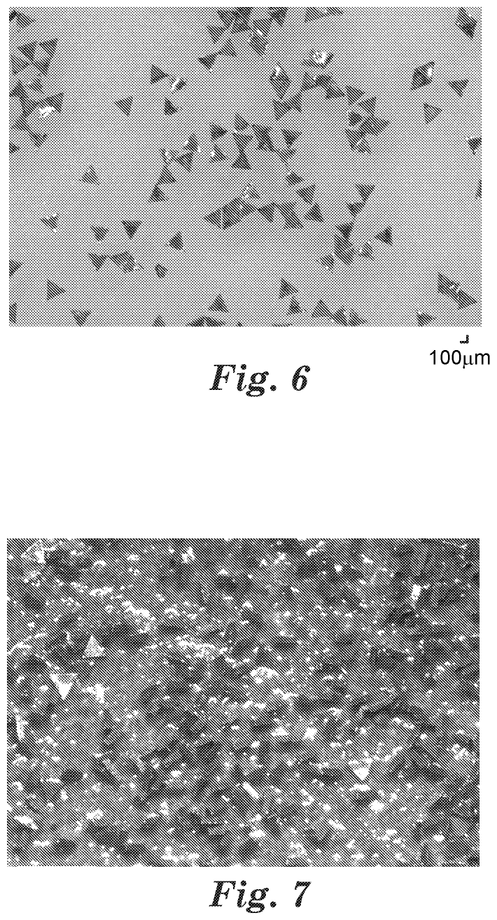

Examples 2 to 5 were prepared in a similar way to Example 1, except following the process conditions listed in Table 2. FIG. 6 shows an optical microscope image of iron coated abrasive particles from EX-2

### Example 6 (EX-6)

Alumina fiber chopped to about 200 micrometers (μm) in length, SAP5, (100 g) was charged into a glass fit funnel-type fluidized bed chemical vapor deposition (CVD) reactor with 45 millimeters (mm) inner diameter reactor (as described, for example, in Example 1 of U.S. Pat. No. 5,673,148 (Morris et al)). The reactor was wrapped with electric heating tape and heated to 250° C. The temperature was monitored using a thermocouple in the fluidized bed. The bed of alumina particles was fluidized with a stream of 1.35 liter per minute (L/min) forming gas introduced into the reactor through the glass frit (i.e., from the bottom of the bed of alumina fibers). Iron pentacarbonyl vapor was simultaneously introduced into the reactor, above the glass frit, in a stream of 600 cc/min forming gas by bubbling the carrier gas through iron pentacarbonyl in a chamber separate from the reactor. After 40 minutes of total reaction time, the power to the electric heating tape and the forming gas through the iron pentacarbonyl were turned off. The alumina particles were cooled under a flow of forming gas through the glass frit to about 40° C. and were collected to give alumina particles with a shiny, metallic coating.

### Example 7 (EX-7)

Silicon carbide abrasive with a grain sized of 150, SiC, (150 g) was charged into a glass frit funnel-type fluidized bed chemical vapor deposition (CVD) reactor with 45 millimeters (mm) inner diameter reactor (as described, for example, in Example 1 of U.S. Pat. No. 5,673,148 (Morris et al)). The reactor was wrapped with electric heating tape and heated to 200° C. The temperature was monitored using a thermocouple in the fluidized bed. The bed of abrasive particles was fluidized with a stream of 1.9 L/min nitrogen introduced into the reactor through the glass frit (i.e., from the bottom of the bed of alumina fibers). Iron pentacarbonyl vapor was simultaneously introduced into the reactor, above the glass frit, in a stream of 600 cc/min nitrogen by bubbling the carrier gas through iron pentacarbonyl in a chamber separate from the reactor. After 60 minutes of total reaction time, the power to the electric heating tape and the nitrogen through the iron pentacarbonyl were turned off. The alumina particles were cooled under a flow of nitrogen through the glass fit to about 40° C. and were collected to give abrasive particles with a shiny, metallic coating.

TABLE 2
The experimental parameters for examples 1-7.

| | | Fluidized | | Carrier | |
|---|---|---|---|---|---|
| | | gas | | gas, | |
| | | stream, | | volumetric | Total |
| | Abrasive | volumetric | | rate in | reaction |
| | particle, | rate in | Metal | cc/ | time, |
| Example | mass in g | L/minute | precursor | minute | minutes |
| EX-1 | SAP1, 100 | N₂, 3.6 | Iron | N₂, 300 | 80 |
| | | | Pentacarbonyl | | |
| EX-2 | SAP2, 100 | N₂, 4.8 | Iron | N₂, 600 | 40 |
| | | | Pentacarbonyl | | |
| EX-3 | SAP3, 100 | N₂, 7.0 | Iron | N₂, 600 | 40 |
| | | | Pentacarbonyl | | |
| EX-4 | SAP4, 100 | N₂, 3.4 | Iron | N₂, 600 | 40 |
| | | | Pentacarbonyl | | |
| EX-5 | SAP4, 100 | Forming | Iron | Forming | 40 |
| | | gas, 3.4 | Pentacarbonyl | gas, 600 | |
| EX-6 | SAP5, 100 | forming | Iron | Forming | 40 |
| | | gas, 1.35 | Pentacarbonyl | gas, 600 | |
| EX-7 | SiC, 150 | N₂, 1.9 | Iron | N₂, 600 | 60 |
| | | | Pentacarbonyl | | |

### Example 8 (EX-8)

A rotary tube furnace (Model: TF-1200X-5L-R-III, Manufacturer: MTI Corporation, Location: Richmond, Calif.) with a 5″ Pyrex glass tube was loaded with 250 g of SAP2. There were two inlets: a purge/dilution gas stream of nitrogen set to a flow rate of 500 cc/min using a mass flow controller and a second inlet connected to a stainless steel bubbler that contained the iron pentacarbonyl. There were valves to isolate the bubbler and a bypass line that was used during the initial and final purges. The nitrogen flow for the bubbler inlet was set to a flow rate of 1.001/min using a mass flow controller. The furnace was set to 200° C. The tube was set to an angle of −15° (inlet lower than outlet) and rotated at 10 RPM. The furnace was purged while it was heating up to temperature (about 30 minutes). Then the iron pentacarbonyl was introduced by opening the valves to the bubbler and closing the bypass valve. After an hour the theoretical amount of iron had been introduced to achieve the desired coating thickness and the bubbler was again isolated from the system. The furnace was turned off and the coated abrasive was cooled under a nitrogen gas stream (1.501/min total flow rate). After cooling to room temperature, the iron coated SAP2 particles were collected and handled in the air.

### Example 9 (EX-9)

The procedure given for EX-8 was repeated with the following modifications: the tube furnace was loaded with 250 g of SAP6, the bubbler flow rate was set to 0.75 Imin, the purge time was 1 hour, and the reaction time was 80 min.

### Example 10 (EX-10)

The procedure given for EX-8 was repeated with the following modifications: the tube furnace was loaded with 250 g of SAP4, the bubbler flow rate was set to 0.75 L/min, the purge time was 1.5 hours, and the reaction time was 80 min.

TABLE 3
Properties of the iron coated particles

| | Magnetic Properties | | | Elemental | Coating |
|---|---|---|---|---|---|
| | M_{S}, | H_{C}, | M_{R}/M_{S}, | analysis ratio, | Thickness, |
| Example | emu/g | Oe | % | Al:Fe | nm |
| EX-1 | 2.13 | 165 | 60 | 10.6 | 60 |
| EX-2 | 2.43 | 97 | 43 | 13.5 | 148 |
| EX-3 | 2.97 | 39 | 34 | 10.8 | 295 |
| EX-4 | 2.13 | 110 | 47 | 17.8 | 72 |
| EX-5 | 2.31 | 70 | 36 | 15.5 | 75 |
| EX-6 | 0.72 | 177 | 27 | 22.2 | 20 |
| EX-7 | 3.23 | 40 | 45 | 17.4 | 134 |
| | | | | (Si:Fe) | |
| EX-8 | 1.58 | 79 | 28 | 18.0 | 113 |
| EX-9 | 1.26 | 51 | 29 | 9.2 | 491 |
| EX-10 | 1.98 | 43 | 19 | 17.9 | 75 |

### Example 11 (EX-11)

An abrasive article was prepared by coating a 110 gsm paper backing with phenolic resin at a thickness of 1 mil (0.025 mm). Once coated, the backing was placed on top of a 4 inches×2 inches×1 inch (10.16 cm×5.085 cm×2.54 cm) N42 Neodymium magnet (Applied Magnets, Plano, Tex., USA) with a field strength of 3.0 kOe measured at the center of the magnet. A salt shaker-type dispenser was used to uniformly coat 4.9 grains per 4 inches×6 inches (10.16 cm×15.24 cm) of iron coated SAP4 (EX-4) onto the resin coated backing. The resin coated backing was then lifted straight upward off the magnet and placed in a solvent rated oven. The sample was kept in the oven for 5 hours at 200° F. (93° C.). FIG. 7 shows an optical microscope image of the abrasive article with magnetically oriented abrasive particles from EX-8.

### Comparative Example 1 (CEX-1)

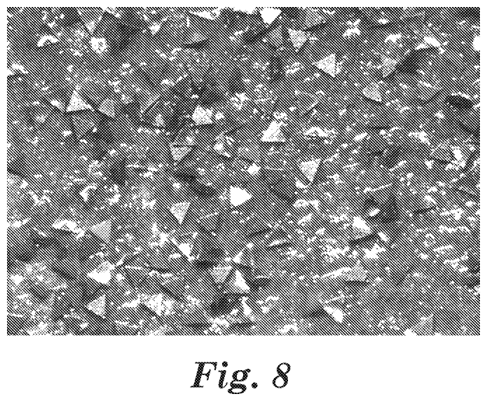

A comparative abrasive article of the same construction and method was created with the exception that the article was never subjected to a magnetic field. When the samples were viewed with a microscope it was apparent that the abrasive particles of EX-8 had substantial upright orientation, in stark contrast of the particles of CEX-1, which were substantially lying flat and not oriented. FIG. 8 shows an optical microscope image of the abrasive article with non-oriented abrasive particles from CEX-1.

All references and publications cited herein are expressly incorporated herein by reference in their entirety into this disclosure. Illustrative embodiments of this invention are discussed and reference has been made to possible variations within the scope of this invention. For example, features depicted in connection with one illustrative embodiment may be used in connection with other embodiments of the invention. These and other variations and modifications in the invention will be apparent to those skilled in the art without departing from the scope of the invention, and it should be understood that this invention is not limited to the illustrative embodiments set forth herein. Accordingly, the invention is to be limited only by the claims provided below and equivalents thereof.

1. A magnetizable abrasive particle, comprising:
a ceramic particle having an outer surface; and
a continuous metal coating on the outer surface;
wherein the core hardness of the ceramic particle is at least 15 GPa;
wherein the continuous metal coating comprises iron, cobalt or an alloy of iron and cobalt; and
wherein the thickness of the continuous metal coating is less than 1000 nm.

2. The magnetizable abrasive particle of claim 1, wherein the continuous metal coating consists essentially of iron, cobalt or alloy of iron and cobalt.

3. The magnetizable abrasive particle of claim 1, wherein an aspect ratio of the ceramic particle is more than 1.73.

4. The magnetizable abrasive particle of claim 1, wherein the metal coating of the abrasive particle has a coercivity (H_{C}) of less than 200 Oe.

5. The magnetizable abrasive particle of claim 1, wherein the metal coating on the abrasive particle has a ratio of magnetic remanence (M_{R}) to magnetic saturation (M_{S}) of less than 65%.

6. The magnetizable abrasive particle of claim 1, wherein the ceramic particle comprises alpha alumina.

7. The magnetizable abrasive particle of claim 1, wherein the ceramic particle comprises a spheroid particle.

8. The magnetizable abrasive particle of a claim 1, wherein the ceramic particle comprises ceramic rods.

9. The magnetizable abrasive particle claim 1, wherein the ceramic particle comprises ceramic platelets.

10. The magnetizable abrasive particle claim 9, wherein the ceramic platelets comprise ceramic truncated triangular pyramids.

11. A method of making magnetizable abrasive particles, comprising:
providing ceramic particles, each ceramic particle having a respective outer surface;
coating the outer surfaces of ceramic particles with a continuous metal coating through chemical vapor deposition;
wherein the continuous metal coating comprises iron, cobalt or an alloy of iron and cobalt.

12. The method of claim 11, wherein said chemical vapor deposition is carried out at essentially atmospheric pressure.

13. The method of claim 11, wherein said chemical vapor deposition is carried out in a fluidized bed.

14. The method of claim 11, wherein said chemical vapor deposition is carried out in a rotary kiln.

15. The method of claim 11, wherein the magnetizable abrasive particles have less than 25% agglomerated magnetizable abrasive particles.

16. The method of claim 11, wherein the magnetizable abrasive particles are essentially free of agglomerated magnetizable abrasive particles.

17. Magnetizable abrasive particles prepared according to any one of claim 11.

18. An abrasive article comprising a plurality of magnetizable abrasive particles of claim 1.

19. A method for making an abrasive article comprising:
providing magnetizable abrasive particles of claim 1 on a substrate having a major surface; and
applying a magnetic field to the magnetizable abrasive particles such that a majority of the magnetizable abrasive particles are oriented substantially perpendicular to the major surface.
